(19) United States
(12) Patent Application Publication
(10) Pub. No.: US 2026/0369313 A1
(43) Pub. Date: Nov. 19, 2026

(54) CONTROL CIRCUIT OF MEMORY DEVICE AND CONTROL METHOD THEREOF

(71) Applicant: NANYA TECHNOLOGY CORPORATION, New Taipei City (TW)

(72) Inventor: Yao-Chang Chiu, New Taipei City (TW)

(73) Assignee: NANYA TECHNOLOGY CORPORATION, New Taipei City (TW)

(21) Appl. No.: 19/209,755

(22) Filed: May 15, 2025

(51) Int. Cl. G11C 7/14; G11C 7/10; G11C 8/18

(52) U.S. Cl. CPC G11C 7/14; G11C 7/1069; G11C 8/18

(57) ABSTRACT

A control circuit of a memory device and control method for controlling the control circuit are provided. The control circuit includes a voltage generator, a signal transmitting circuit and an adjusting circuit. The voltage generator provides a reference high voltage. The signal transmitting circuit is driven by the reference high voltage and transmits a data strobe (DQS) signal. The adjusting circuit controls the voltage generator to adjust a voltage value of the reference high voltage to a target voltage value.

### BACKGROUND

### Technical Field

The disclosure generally relates to a control circuit, and more particularly to a control circuit of a memory device and control method for controlling the control circuit.

### Description of Related Art

A memory device includes a control circuit. The control circuit receives a data strobe (DQS) signal and transmits the DQS signal. The control circuit is driven based on a reference high voltage. When a voltage value of the reference high voltage changes, a timing of the DQS signal would also change. Therefore, how to stable the reference high voltage is one of the research and development focuses of those skilled in the art.

### SUMMARY

The disclosure provides a control circuit of a memory device and control method for controlling the control circuit. The control circuit can stable the reference high voltage, so as let a timing of the DQS signal stable.

In an embodiment of the disclosure, the control circuit includes a voltage generator, signal transmitting circuit and an adjusting circuit. The voltage generator provides a reference high voltage. The signal transmitting circuit is coupled to the voltage generator. The signal transmitting circuit is driven by the reference high voltage and transmits a data strobe (DQS) signal. The adjusting circuit is coupled to the voltage generator. The adjusting circuit controls the voltage generator to adjust a voltage value of the reference high voltage to a target voltage value.

In an embodiment of the disclosure, the control method for controlling the control circuit of the memory device. The control circuit includes a voltage generator and a signal transmitting circuit. The control method comprises: providing, by the voltage generator, a reference high voltage; controlling the voltage generator to adjust a voltage value of the reference high voltage to a target voltage value; and driving the signal transmitting circuit to transmit a data strobe signal by the reference high voltage.

Based on the above, the voltage value of the reference high voltage is adjusted to the target voltage value. Therefore, the reference high voltage is stable. In this way, the timing of the DQS signal transmitted by the signal transmitting circuit is stable.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a schematic diagram of a control circuit according to an embodiment of the disclosure.

FIG. 2 illustrates a schematic diagram of a voltage generator according to an embodiment of the disclosure.

FIG. 3 illustrates a schematic diagram of a control circuit according to an embodiment of the disclosure.

FIG. 4 illustrates operating schematic diagrams according to an embodiment of the disclosure.

FIG. 5 illustrates a schematic diagram of a control circuit according to an embodiment of the disclosure.

FIG. 6 illustrates operating schematic diagrams according to an embodiment of the disclosure.

FIG. 7 illustrates a flow chart of a control method according to an embodiment of the disclosure.

### DESCRIPTION OF THE EMBODIMENTS

A disclosure may be understood by reference to the following detailed description, taken in conjunction with the drawings as described below. It is noted that, for purposes of illustrative clarity and being easily understood by the readers, various drawings of this disclosure show a portion of an electronic device, and certain elements in various drawings may not be drawn to scale. In addition, the number and dimension of each device shown in drawings are only illustrative and are not intended to limit the scope of a disclosure.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to...”. Thus, when the terms “include”, “comprise” and/or “have” are used in the description of a disclosure, the corresponding features, areas, steps, operations and/or components would be pointed to existence, but not limited to the existence of one or a plurality of the corresponding features, areas, steps, operations and/or components.

It will be understood that when an element is referred to as being “coupled to”, “connected to”, or “conducted to” another element, it may be directly connected to the other element and established directly electrical connection, or intervening elements may be presented therebetween for relaying electrical connection (indirectly electrical connection). In contrast, when an element is referred to as being “directly coupled to”, “directly conducted to”, or “directly connected to” another element, there are no intervening elements presented.

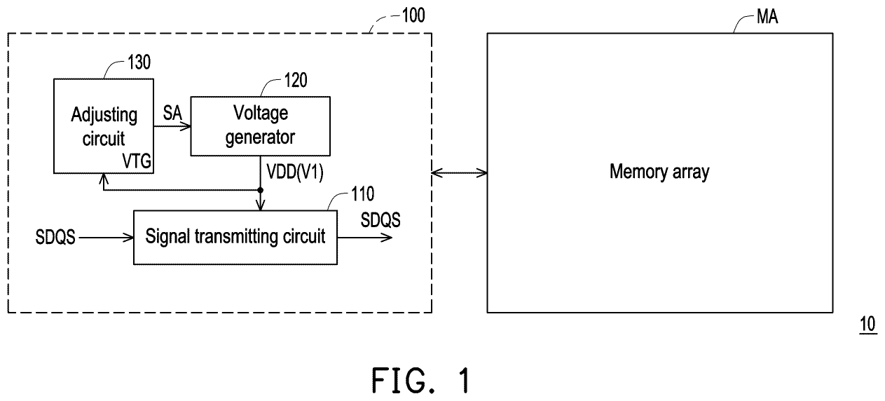

Please refer to FIG. 1, FIG. 1 illustrates a schematic diagram of a control circuit according to an embodiment of the disclosure. In the embodiment, the control circuit 100 controls a memory device 10. The control circuit 100 is a memory controller of the memory device 10. The control circuit 100 can operate a write operation, a read operation, refresh operation, erase operation on memory array MA of the memory device 10, but the disclosure is not limited thereto. In the embodiment, the control circuit 100 includes a voltage generator 110, a signal transmitting circuit 120 and an adjusting circuit 130. The voltage generator 110 provides a reference high voltage VDD. The signal transmitting circuit 120 is coupled to the voltage generator 110. The signal transmitting circuit 120 is driven by the reference high voltage and transmits a data strobe (DQS) signal SDQS. The adjusting circuit 130 is coupled to the voltage generator 110. The adjusting circuit 130 controls the voltage generator 110 to adjust a voltage value V1 of the reference high voltage VDD to a target voltage value VTG.

It should be noted, the voltage value V1 of the reference high voltage is adjusted to the target voltage value VTG. Therefore, the reference high voltage VDD is stable. In this way, the timing of the DQS signal SDQS transmitted by the signal transmitting circuit 120 is stable.

In the embodiment, the adjusting circuit 130 receives the reference high voltage VDD and senses the voltage value V1 of the reference high voltage VDD. When the voltage value V1 of the reference high voltage VDD is equal to target voltage value VTG, the adjusting circuit 130 controls the voltage generator 110 to maintain the voltage value V1 of the reference high voltage VDD.

When the voltage value V1 of the reference high voltage VDD is lower than the target voltage value VTG, the adjusting circuit 130 controls the voltage generator 110 to increase the voltage value V1 of the reference high voltage to the target voltage value VTG. When the voltage value V1 of the reference high voltage VDD is higher than the target voltage value VTG, the adjusting circuit 130 controls the voltage generator 110 to decrease the voltage value V1 of the reference high voltage VDD to the target voltage value VTG.

In the embodiment, the adjusting circuit 130 use an adjusting signal SA to control the voltage generator 110. For example, the adjusting signal SA includes a trimming code or a trimming voltage. The voltage generator 110 changes the voltage value V1 of the reference high voltage VDD in response to the trimming code or the trimming voltage.

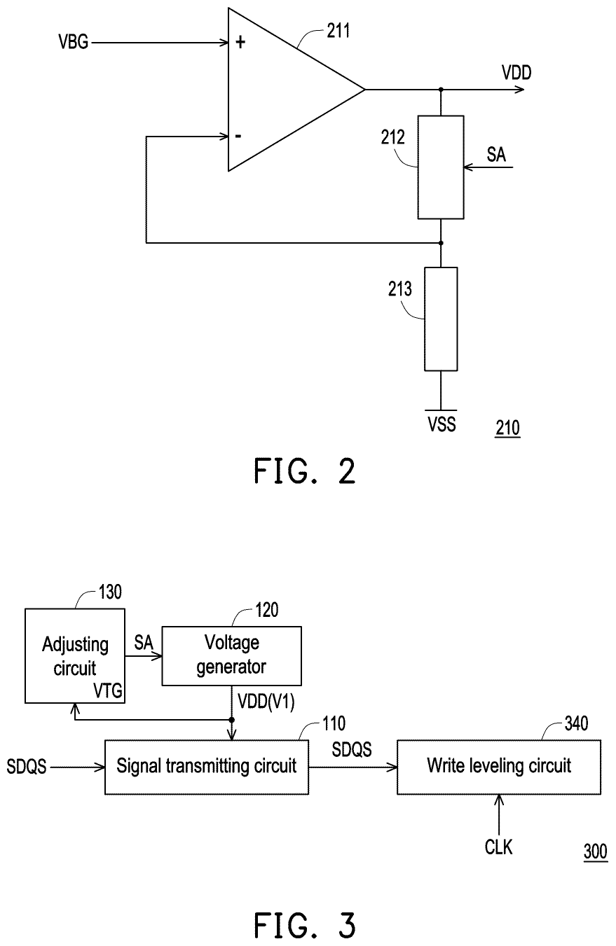

Please refer to FIG. 1 and FIG. 2, FIG. 2 illustrates a schematic diagram of a voltage generator according to an embodiment of the disclosure. In the embodiment, the voltage generator 210 includes an operational amplifier 211, a variable resistor circuit 212 and a resistor 213. A non-inverting input terminal of the operational amplifier 211 receives a bandgap voltage VBG. An output terminal of the operational amplifier 211 outputs the reference high voltage VDD. The variable resistor circuit 212 is coupled between the output terminal of the operational amplifier 211 and an inverting input terminal of the operational amplifier 211. The resistor 213 is coupled between the inverting input terminal of the operational amplifier 211 and a reference low voltage VSS.

In the embodiment, the adjusting circuit 130 is coupled to the output terminal of the operational amplifier 211 and the variable resistor circuit 212. The adjusting circuit 130 senses the voltage value V1 of the reference high voltage VDD from the output terminal of the operational amplifier 211. In the embodiment, the adjusting circuit 130 adjusts a resistance value of the variable resistor circuit 212 using the adjusting signal SA. The resistance value of the variable resistor circuit 212 can be trimmed in response to the adjusting signal SA.

When the voltage value V1 of the reference high voltage VDD is different from the target voltage value VTG, the adjusting circuit 130 adjusts a resistance value of the variable resistor circuit 212. When the voltage value V1 of the reference high voltage VDD is lower than the target voltage value VTG, the resistance value of the variable resistor circuit 212 is increased. Therefore, the voltage value V1 of the reference high voltage VDD is increased, so as to reach to the target voltage value VTG. When the voltage value V1 of the reference high voltage VDD is higher than the target voltage value VTG, the resistance value of the variable resistor circuit 212 is decreased. Therefore, the voltage value V1 of the reference high voltage VDD is decreased, so as to reach to the target voltage value VTG.

For example, the variable resistor circuit 212 may be implemented by a variable resistor. The resistance value of the variable resistor circuit 212 can be trimmed in response to the trimming voltage of the adjusting signal SA, but the disclosure is not limited thereto. For example, the variable resistor circuit 212 may be implemented by circuit network including resistors and switches. The variable resistor circuit 212 can select a connection number of resistors based on switching state of the switches in response to the trimming code of the adjusting signal SA.

In the embodiment, the adjusting circuit 130 compares the voltage value V1 of the reference high voltage VDD and the target voltage value VTG to generate a voltage difference value between the voltage value V1 and the target voltage value VTG. The adjusting circuit 130 computes a target resistance value of the variable resistor circuit 212 corresponding to the target voltage value VTG according to the voltage difference value and a resistance value of the resistor 213. In the embodiment, the adjusting circuit 130 may be implemented by a voltage sensor and a computing circuit, but the disclosure is not limited thereto.

Please refer to FIG. 3, FIG. 3 illustrates a schematic diagram of a control circuit according to an embodiment of the disclosure. In the embodiment, the control circuit 300 includes the voltage generator 110, the signal transmitting circuit 120, the adjusting circuit 130 and a write leveling circuit 340. Operations the voltage generator 110, the signal transmitting circuit 120, the adjusting circuit 130 have been clearly explained in the embodiments of FIG. 1 and FIG. 2, so it will not be repeated here.

In the embodiment, the write leveling circuit 340 is coupled to the signal transmitting circuit. The write leveling circuit 340 performs a write leveling operation on the DQS signal SDQS. The write leveling circuit 340 receives the DQS signal SDQS and a clock CLK. The write leveling circuit 340 aligns an edge of the DQS signal SDQS according to the clock CLK. For example, the write leveling circuit 340 controls a write leveling setup time (tWLS) and a write leveling hold time (tWLH) of the DQS signal SDQS.

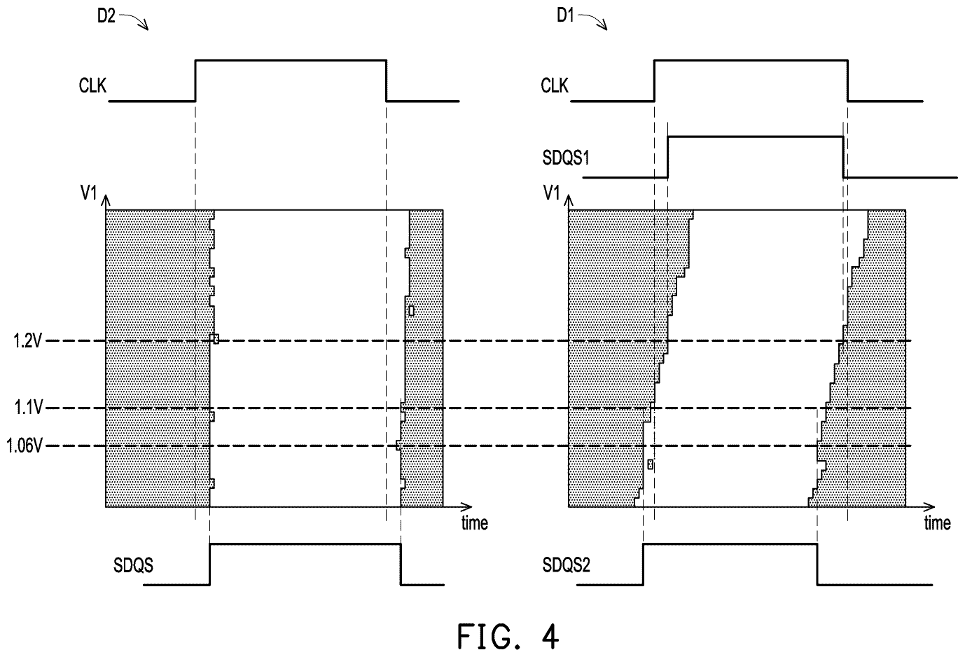

Please refer to FIG. 3 and FIG. 4, FIG. 4 illustrates operating schematic diagrams according to an embodiment of the disclosure. FIG. 4 illustrates the operating schematic diagrams D1 and D2. The operating schematic diagrams D1 displays a result of a write leveling operation without the adjusting circuit 130. A vertical axis of the operating schematic diagrams D1 is the voltage value V1 of the of the reference high voltage VDD. A unit of the vertical axis is “volt”. A horizontal axis of the operating schematic diagrams D1 is time. A unit of the horizontal axis is “picosecond (ps)”. In the operating schematic diagrams D1, a timing of the DQS signal SDQS is shifted with the voltage value V1. When the voltage value V1 changes, the tWLS and the tWLH of the DQS signal SDQS changes. Therefore, the write leveling operation on the DQS signal SDQS is unstable. For example, the target voltage value VTG is 1.1 volts. when the voltage value V 1 is 1.06, the tWLS of the DQS signal SDQS1 is 10 ps and the tWLH of the DQS signal SDQS1 is 40 ps. When the voltage value V 1 is 1.2, the tWLS of the DQS signal SDQS2 is 20 ps and the tWLH of the DQS signal SDQS2 is 5 ps. It should be noted, the tWLS performance obtained at different voltages differs by up to 30 ps, which can easily lead to unstable bootup.

The operating schematic diagrams D2 displays a result of a write leveling operation with the adjusting circuit 130. A vertical axis of the operating schematic diagrams D2 is the voltage value V1 of the of the reference high voltage VDD. A unit of the vertical axis is “volt”. A horizontal axis of the operating schematic diagrams D2 is time. A unit of the horizontal axis is “picosecond (ps)”. In the operating schematic diagrams D2, when the voltage value V1 changes, the voltage value V1 is adjusted to the target voltage value VTG. Therefore, the write leveling operation on the DQS signal SDQS is stable.

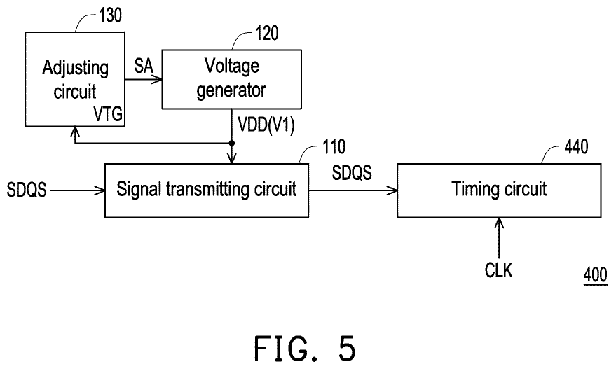

Please refer to FIG. 5, FIG. 5 illustrates a schematic diagram of a control circuit according to an embodiment of the disclosure. In the embodiment, the control circuit 400 includes the voltage generator 110, the signal transmitting circuit 120, the adjusting circuit 130 and a write leveling circuit 440. Operations the voltage generator 110, the signal transmitting circuit 120, the adjusting circuit 130 have been clearly explained in the embodiments of FIG. 1 and FIG. 2, so it will not be repeated here.

In the embodiment, the timing circuit 440 is coupled to the signal transmitting circuit 120. The write leveling circuit 340 receives the DQS signal SDQS and a clock CLK. The timing circuit 440 determines a time interval between the DQS signal SDQS and the clock CLK of the memory device. In the embodiment, the time interval is data strobe to clock skew (tDQSS).

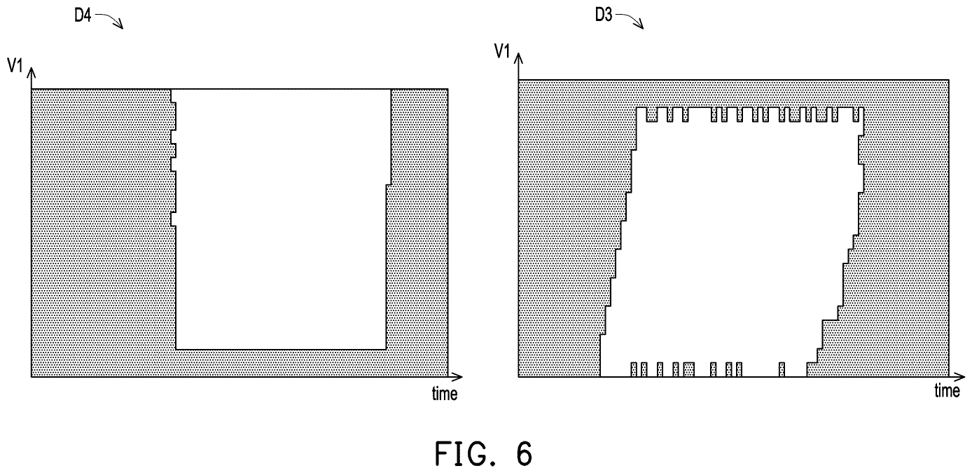

Please refer to FIG. 5 and FIG. 6, FIG. 6 illustrates operating schematic diagrams according to an embodiment of the disclosure. FIG. 6 illustrates the operating schematic diagrams D3 and D4. The operating schematic diagrams D3 displays a result without the adjusting circuit 130. A vertical axis of the operating schematic diagrams D3 is the voltage value V1 of the of the reference high voltage VDD. A horizontal axis of the operating schematic diagrams D1 is time. In the operating schematic diagrams D1, a tDQSS window is shifted with the voltage value V1. Therefore, the tDQSS is obviously affected by changes in the voltage value V1.

The operating schematic diagrams D4 displays a result with the adjusting circuit 130. A vertical axis of the operating schematic diagrams D2 is the voltage value V1 of the of the reference high voltage VDD. A horizontal axis of the operating schematic diagrams D2 is time. In the operating schematic diagrams D2, when the voltage value V1 changes, the voltage value V1 is adjusted to the target voltage value VTG. Therefore, the write leveling operation on the tDQSS window is stable.

In some embodiment, the control circuit 400 further includes the write leveling circuit 340 in the embodiment of FIG. 3.

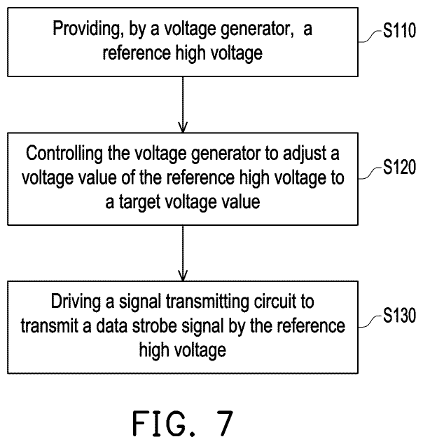

Please refer to FIG. 1 and FIG. 7, FIG. 7 illustrates a flow chart of a control method according to an embodiment of the disclosure. In the embodiment, the control method S100 is used for controlling the control circuit 100. The control method S100 includes steps S110, S120 and S130. In the step S110, the voltage generator 110 provides a reference high voltage VDD. In the step S120, the adjusting circuit 130 controls the voltage generator 110 to adjust a voltage value V1 of the reference high voltage VDD to a target voltage value VTG. In the step S130, the signal transmitting circuit 120 is driven by the reference high voltage and transmits the DQS signal SDQS. Operations of the steps S110 to S130 have been clearly explained in the embodiments of FIG. 1 and FIG. 2, so it will not be repeated here.

In view of the foregoing, the voltage value of the reference high voltage is adjusted to the target voltage value. Therefore, the reference high voltage is stable. In this way, the timing of the DQS signal transmitted by the signal transmitting circuit is stable. Furthermore, when the DQS signal transmitted by the signal transmitting circuit is stable, the write leveling operation and/or the determining of the time interval (for example, tDQSS) between the DQS signal and the clock is stable.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A control circuit of a memory device, comprising:
a voltage generator, configured to provide a reference high voltage;
a signal transmitting circuit, coupled to the voltage generator, and configured to be driven by the reference high voltage and transmit a data strobe signal; and
an adjusting circuit, coupled to the voltage generator, and configured to control the voltage generator to adjust a voltage value of the reference high voltage to a target voltage value.

2. The control circuit of claim 1, wherein when the voltage value of the reference high voltage is lower than the target voltage value, the adjusting circuit controls the voltage generator to increase the voltage value of the reference high voltage to the target voltage value.

3. The control circuit of claim 1, wherein when the voltage value of the reference high voltage is higher than the target voltage value, the adjusting circuit controls the voltage generator to decrease the voltage value of the reference high voltage to the target voltage value.

4. The control circuit of claim 1, wherein the voltage generator comprises:
an operational amplifier, a non-inverting input terminal of the operational amplifier receives a bandgap voltage, an output terminal of the operational amplifier outputs the reference high voltage;
a variable resistor circuit, coupled between the output terminal of the operational amplifier and an inverting input terminal of the operational amplifier; and
a resistor, coupled between the inverting input terminal of the operational amplifier and a reference low voltage.

5. The control circuit of claim 4, wherein the adjusting circuit is coupled to the output terminal of the operational amplifier and the variable resistor circuit.

6. The control circuit of claim 5, wherein:
the adjusting circuit senses the voltage value of the reference high voltage from the output terminal of the operational amplifier, and
when the voltage value of the reference high voltage is different from the target voltage value, the adjusting circuit adjusts a resistance value of the variable resistor circuit.

7. The control circuit of claim 6, wherein the adjusting circuit compares the voltage value of the reference high voltage and the target voltage value to generate a voltage difference value between the voltage value of the reference high voltage and the target voltage value.

8. The control circuit of claim 7, wherein the adjusting circuit computes a target resistance value of the variable resistor circuit corresponding to the target voltage value according to the voltage difference value and a resistance value of the resistor.

9. The control circuit of claim 1, further comprising:
a write leveling circuit, coupled to the signal transmitting circuit, and configured to perform a write leveling operation on the data strobe signal.

10. The control circuit of claim 1, further comprising:
a timing circuit, coupled to the signal transmitting circuit, and configured to determining a time interval between the data strobe signal and a clock of the memory device.

11. A control method for controlling a control circuit of a memory device, wherein the control circuit comprises a voltage generator and a signal transmitting circuit, wherein the control method comprises:
providing, by the voltage generator, a reference high voltage;
controlling the voltage generator to adjust a voltage value of the reference high voltage to a target voltage value; and
driving the signal transmitting circuit to transmit a data strobe signal by the reference high voltage.

12. The control method of claim 11, wherein adjusting the voltage value of the reference high voltage to the target voltage value comprises:
when the voltage value of the reference high voltage is lower than the target voltage value, controlling the voltage generator to increase the voltage value of the reference high voltage to a target voltage value.

13. The control method of claim 11, wherein adjusting the voltage value of the reference high voltage to the target voltage value comprises:
when the voltage value of the reference high voltage is higher than the target voltage value, the adjusting circuit control the voltage generator to decrease the voltage value of the reference high voltage to target voltage value.

14. The control method of claim 11, wherein the voltage generator comprises:
an operational amplifier, a non-inverting input terminal of the operational amplifier receives a bandgap voltage, an output terminal of the operational amplifier outputs the reference high voltage;
a variable resistor circuit, coupled between the output terminal of the operational amplifier and an inverting input terminal of the operational amplifier; and
a resistor, coupled between the inverting input terminal of the operational amplifier and a reference low voltage.

15. The control method of claim 14, wherein adjusting the voltage value of the reference high voltage to the target voltage value comprises:
sensing the voltage value of the reference high voltage from the output terminal of the operational amplifier; and
when the voltage value of the reference high voltage is different from the target voltage value, adjusting a resistance value of the variable resistor circuit.

16. The control method of claim 14, wherein adjusting the voltage value of the reference high voltage to the target voltage value comprises:
comparing the voltage value of the reference high voltage and the target voltage value to generate a voltage difference value between the voltage value of the reference high voltage and the target voltage value.

17. The control method of claim 16, wherein adjusting the voltage value of the reference high voltage to the target voltage value further comprises:
computing a target resistance value of the variable resistor circuit corresponding to the target voltage value according to the voltage difference value and a resistance value of the resistor.
